(19) United States
(12) Patent Application Publication
(10) Pub. No.: US 2026/0118762 A1
(43) Pub. Date: Apr. 30, 2026

(54) POLYMER FOR PHOTOLITHOGRAPHIC MEDIUM COMPOSITION, AND PHOTOLITHOGRAPHIC MEDIUM COMPOSITION

(71) Applicant: TAN KAH KEE INNOVATION LABORATORY, Xiamen, Fujian (CN)

(72) Inventors: Aiqiang ZHANG, Xiamen, Fujian (CN); Jialong WU, Xiamen, Fujian (CN); Yimin JIANG, Xiamen, Fujian (CN); Dong SHI, Xiamen, Fujian (CN); Renzhi CHEN, Xiamen, Fujian (CN); Yuan CHEN, Xiamen, Fujian (CN)

(73) Assignee: TAN KAH KEE INNOVATION LABORATORY, Xiamen, Fujian (CN)

(21) Appl. No.: 19/480,322

(22) PCT Filed: Jun. 30, 2023
(86) PCT No.: PCT/CN2023/105073

§ 371 Date: Oct. 30, 2025

(30) Foreign Application Priority Data
Jun. 15, 2023 (CN) 202310712932.8

(51) Int. Cl. G03F 7/038; C08G 61/10

(52) U.S. Cl. CPC G03F 7/0384; C08G 61/10; G03F 7/0388; C08G 2261/122; C08G 2261/124; C08G 2261/1422; C08G 2261/148; C08G 2261/149; C08G 2261/312; C08G 2261/314; C08G 2261/90

(57) ABSTRACT

The present disclosure relates to a polymer for a photolithographic medium composition, and the photolithographic medium composition. The polymer has a structural unit represented by general formula (1) below. The polymer of the present disclosure maintains a carbon-rich structure (i.e., a polybenzene ring structure) while a sec-hydroxyl structure is introduced into the structure. The sec-hydroxyl structure can provide cross-linking sites during the film formation process of the material, which can improve the overall cross-linking density of the material, and consequently improve the etching resistance of the material. In addition, the sec-hydroxyl structure can serve as polar interaction sites, and has a strong movement ability, contributing to the improvement of the ability to interact with solvents. Thus, the solubility performance of the material is improved. The polymer of the present disclosure has excellent performance in the solubility and etching resistance, and the solubility of the polymer is improved while the etching resistance is considered. Thus, the polymer is very suitable as the material for an etching-resistant medium layer.

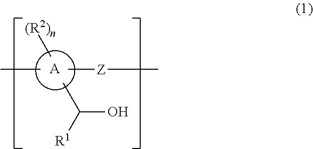

### FIELD

The present disclosure relates to a polymer for a photolithographic medium composition, and the photolithographic medium composition.

### BACKGROUND

The lithographic process is one of the most important processes in manufacturing semiconductor integrated circuit chips. Specifically, the lithographic process transfers the fine patterns of the integrated circuit on the mask plate to the photoresist by utilizing the light-sensitive function of photoresist. Then the final pattern is formed on the substrate medium by a subsequent etching process, or ion implantation is achieved by an ion implantation process. With the development of the semiconductor integrated circuit industry, integrated circuit patterns prepared by the lithographic process have become increasingly finer, evolving from tens of nanometers to several nanometers. In typical lithographic process techniques, the photoresist forms a photolithography pattern after exposure and development, and acts as a mask for etching the underlying substrate material. Therefore, it is required that the photoresist layer must have a certain degree of etching resistance. In addition, as the lithographic process develops and the requirements for finer patterns, the thickness of the photoresist layer had to be reduced to achieve better resolution, resulting in the photoresist alone could not fully function as mask. Therefore, a multi-layer stacking process (for example, photoresist-anti-reflective interlayer-etching resistant interlayer-substrate material layer) must be designed to meet the needs for producing the pattern with a high aspect ratio. After forming a photolithography pattern on the photoresist layer, the pattern can be transferred layer by layer to various intermediate layers and substrate material layer by utilizing the different etching rate of the etching gas on different material layers. In this process, the material in the upper layer acts as the etch mask for the material in the next layer.

In addition, when producing thin films of materials, the spin coating is cheaper than chemical vapor deposition (CVD) process, and the interlayers formed by the spin coating has better filling and planarizating properties. Therefore, the material of the intermediate medium layers must have good etching resistance, planarizating and anti-reflection properties while taking into account the solubility of the material. Therefore, there is still a need in this field for the photolithographic medium materials with improved etching resistance and consideration of solubility.

### SUMMARY

The present disclosure provides a polymer for a photolithographic medium composition, having a structural unit represented by general formula (1) below

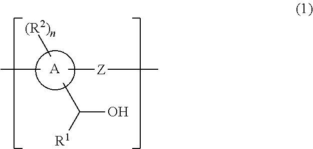

wherein A is a C6-C30 monocyclic or polycyclic aryl,
R² is each independently selected from the group consisting of hydrogen, halogen, cyano, a C1-C8 alkyl, a C2-C8 alkenyl, a C2-C8 alkynyl, —OR¹¹, —SR¹¹, —NR¹¹R¹², an ether group and an ester group;
Z is selected from the group consisting of a single bond, a C1-C10 alkylene substituted by 0 to 3 R^{A}, a C6-C20 arylene substituted by 0 to 3 R^{A}, a C6-C20 aralkylene substituted by 0 to 3 R^{A}, a C4-C20 heteroaralkylene substituted by 0 to 3 R^{A}, and a C1-C10 heteroalkylene substituted by 0 to 3 R^{A};
R¹ is selected from the group consisting of a C1-C10 alkyl substituted by 0 to 3 R^{A}, a C6-C20 aryl substituted by 0 to 3 R^{A}, heteroaryl containing 3 to 20 skeletal ring-forming atoms and containing one or more identical or different heteroatoms substituted by 0 to 3 R^{A}, a heterocyclyl containing 3 to 20 skeletal ring-forming atoms and containing one or more identical or different heteroatoms substituted by 0 to 3 R^{A}, and a cyclic hydrocarbon group containing 3 to 20 carbon atoms substituted by 0 to 3 R^{A};
R^{A} is each independently selected from the group consisting of hydrogen, halogen, cyano, a C1-C8 alkyl, a C2-C8 alkenyl, a C2-C8 alkynyl, —OR¹¹, —SR¹¹, —NR¹¹R¹², an ether group, and an ester group;
R¹¹ and R¹² are each independently selected from the group consisting of hydrogen, a C1-C8 alkyl, a C2-C8 alkenyl and a C2-C8 alkynyl; and
n is 1, 2 or 3.

In one embodiment, the structural unit represented by general formula (1) is the structural unit represented by general formula (2)

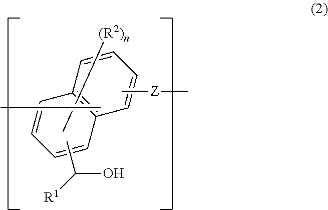

wherein R¹, R², n and Z are as defined above.

In one embodiment, R² is hydroxyl and n is 1 or 2.

In one embodiment, the structural unit represented by general formula (1) is the structural unit represented by general formula (3)

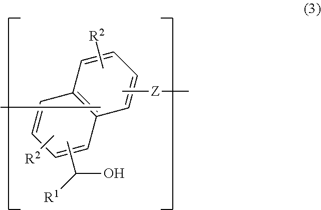

wherein R¹, R², and Z are as defined above.

In one embodiment, R¹ is selected from a C6-C20 aryl substituted by 0 to 3 R^{A}.

In one embodiment, the C6-C20 aryl is selected from the group consisting of phenyl, naphthyl, fluorenyl, anthracenyl, phenanthrenyl, pyrenyl, biphenyl, and triphenyl.

In one embodiment, Z is selected from the following structural formulas

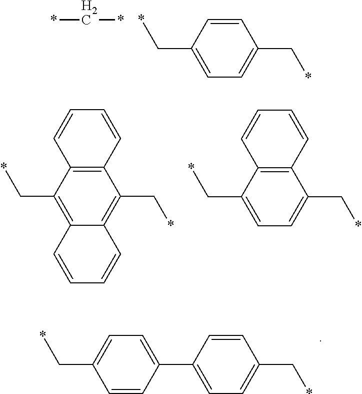

In one embodiment, the polymer further comprises the structural unit represented by general formula (4) and/or the structural unit represented by general formula (5)

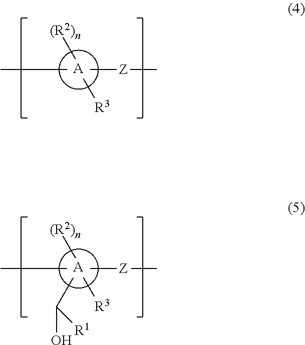

wherein R³ is selected from the group consisting of a C8-C20 aryl methylene, a C8-C30 aryl
methine and a C8-C40 aryl quaternary carbon group;
R¹, R², Z and n are as defined above.

In one embodiment, the structural unit represented by general formula (4) is the structural unit represented by general formula (6)

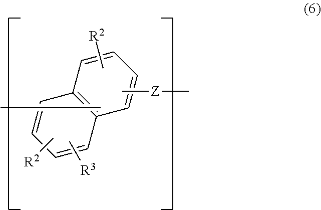

wherein R² is hydroxyl, R³ is a C8-C20 aryl methylene such as anthracenyl methylene, pyrenyl methylene, such as diphenyl methyl, fluorenyl, etc., or a C8-C40 aryl quaternary carbon group such as triphenyl quaternary carbon group, phenylfluorenyl quaternary carbon group, etc.;
the structural unit represented by general formula (5) is the structural unit represented by general formula (7)

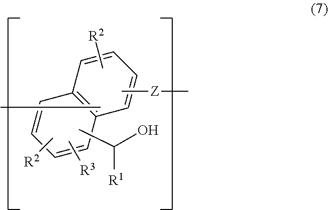

wherein R¹ is selected from a C6-C20 aryl substituted by 0 to 3 R^{A}; preferably, the C6-C20 aryl is selected from the group consisting of phenyl, naphthyl, fluorenyl, anthracenyl, phenanthrenyl, pyrenyl, biphenyl, and triphenyl;
R² is hydroxyl;
R³ is a C8-C20 aryl methylene such as anthracenyl methylene, pyrenyl methylene, naphthyl methylene, phenylmethylene, etc.; or a C8-C30 aryl methine such as diphenyl methyl, fluorenyl, etc.; or a C8-C40 aryl quaternary carbon group such as triphenyl quaternary carbon group, phenylfluorenyl quaternary carbon group, etc.

In one embodiment, the polymer has the weight average molecular weight of 500 to 20000 Da, preferably 1000 to 5000 Da, and the molecular weight distribution of 1.1 to 4.0.

The present disclosure also relates to a photolithographic medium composition, containing an acid generating agent, a cross-linking agent and a medium material, wherein the medium material is the polymer described above in the present disclosure.

In one embodiment, based on the total weight of the photolithographic medium composition, the amount of the medium material is 0.1 to 30 wt %, preferably 2 to 15 wt %, more preferably 3 to 10 wt %;
based on the total weight of the photolithographic medium composition, the amount of the cross-linking agent is 0 to 10 wt %;
based on the total weight of the photolithographic medium composition, the amount of the acid generating agent is 0 to 10 wt %.

In one embodiment, the acid generating agent comprises a thermal acid generating agent and an optional photo acid generating agent,
wherein based on the total weight of the photolithographic medium composition, the content of the thermal acid generating agent is 0 to 10 wt %, preferably 0.01 to 5 wt %, and more preferably 0.01 to 3 wt %; and
based on the total weight of the photolithographic medium composition, the content of the photo acid generating agent is 0 to 10 wt %, preferably 0 to 5 wt %, and more preferably 0.01 to 3 wt %.

In one embodiment, the photolithographic medium composition further comprises a surfactant and a solvent.

In one embodiment, based on the total weight of the photolithographic medium composition, the content of the surfactant is 0 to 20 wt %, more preferably 0.0001 to 5 wt %; and
based on the total weight of the photolithographic medium composition, the content of the solvent is 70 to 99 wt %, and more usually, the content is 85 to 99 wt %.

The present disclosure also relates to a photolithographic medium layer formed from the photolithographic medium composition above.

The polymer of the present disclosure maintains a carbon-rich structure (i.e., a polybenzene ring structure) while a sec-hydroxyl structure is introduced into the structure. The sec-hydroxyl structure can provide cross-linking sites during the film formation process of the material, which can improve the overall cross-linking density of the material, and consequently improve the etching resistance of the material. In addition, the sec-hydroxyl structure can serve as polar interaction sites, and has a strong movement ability, contributing to the improvement of the ability to interact with solvents. Thus, the solubility performance of the material is improved.

The polymer of the present disclosure has excellent performance in the solubility and etching resistance, and the solubility of the polymer is improved while the etching resistance is considered. Thus, the polymer is very suitable as the material for an etching-resistant medium layer.

### BRIEF DESCRIPTION OF THE FIGURES

FIG. 1 is a ¹H-NMR spectrum of polymer A-1 obtained in Example 1.

### DETAILED DESCRIPTION

The present disclosure is described in further detail below in the drawings and embodiments. Through these explanations, the features and advantages of the present disclosure will become clearer and more apparent.

The wording “exemplary” is used herein to mean “used as an example, embodiment, or illustration”. Embodiments described herein as “exemplary” need not be construed as better or superior to other embodiments. The drawings illustrate various aspects of the embodiments, but it is not necessary to draw the drawings to scale unless otherwise noted.

Furthermore, the technical features involved in the different embodiments of this disclosure described below can be combined with each other as long as they do not contradict each other.

### Definitions

It is to be understood that the foregoing brief description and the following detailed description are exemplary and for illustrative purposes only and do not limit the subject matter of the invention in any way. It is important to note that the singular form used in this specification and claims includes the plural form of those referred to, unless otherwise explicitly stated in the text. It should also be noted that the terms “or” and “alternatively” are used to denote “and/or”, unless otherwise indicated. The use of the term “including” and other forms, such as “comprising”, “contain”, “containing”, is not restrictive.

When substituents are represented by conventional chemical formulas written from left to right, the substituents include the chemically equivalent substituents that would result if the structure were written from right to left as well. For example, CH₂O is equivalent to OCH₂.

The term “substituted or unsubstituted” includes both “substituted” and “non-substituted”, wherein “substituted” means that one or more hydrogen atoms on a particular atom has been substituted by a substituent, provided that the valence of the particular atom is normal and the substituted compound is stable, and “unsubstituted” means that the hydrogen atom on a particular atom has not been replaced. For example, substituted or unsubstituted ethyl (for example, if the substituent is a halogen) includes unsubstituted (—CH₂CH₃), monosubstituted (for example, —CH₂CH₂F), multisubstituted (for example, —CHFCH₂F, —CH₂CHF₂, etc.), or completely substituted (—CF₂CF₃). Those skilled in the art will understand that for any group consisting of one or more substituents, no substituent or pattern of substitution will be introduced which is not possible to exist spatially and/or synthesize. When the substituent is an oxo group (i.e., ═O), it means that two hydrogen atoms on the same atom are substituted.

When a variant (for example, R) occurs more than once in the composition or structure of a compound, its definition in each case is independent. Thus, for example, if a group is substituted by 0 to 3 R^{A}, the group may optionally be substituted by up to 3 R^{A}s, and there are independent alternatives for R^{A} in each case. In addition, combinations of substituents and/or variants thereof are allowed only if such combinations result in stable compounds. The term “optional” or optionally” means that the subsequent event or situation described may or may not occur, and that the explanation includes both the occurrence and non-occurrence of the event or situation.

Cm to Cn as used herein means that there are from m to n carbon atoms in the portion. As an example, a “C1-C8” group is a group having 1-8 carbon atoms in the portion, i.e., the group contains 1 carbon atom, 2 carbon atoms, 3 carbon atoms . . . 8 carbon atoms. Thus, for example, “C1-C8 alkyl” means an alkyl group having 1 to 8 carbon atoms, i.e., the alkyl group is selected from methyl, ethyl, propyl, isopropyl, n-butyl, isobutyl, sec-butyl, tert-butyl . . . octyl, etc. As used herein, numerical ranges, such as “1 to 8” refer to each integer within a given range. For example, “1 to 8 carbon atoms” means that the group may have 1 carbon atom, 2 carbon atoms, 3 carbon atoms, 4 carbon atoms, 5 carbon atoms, 6 carbon atoms, 7 carbon atoms, or 8 carbon atoms.

The term “alkyl” refers to an optionally substituted straight chain or an optionally substituted branch-chain saturated aliphatic hydrocarbon group, which is bound to the rest of the molecule by a single bond. As used herein, an alkyl may have 1 to 8 carbon atoms, for example, 1 to 6 carbon atoms, or 1 to 4 carbon atoms, or 1 to 3 carbon atoms. Examples of alkyl herein include, but are not limited to, methyl, ethyl, n-propyl, isopropyl, 2-methyl-1-propyl, 2-methyl-2-propyl, 2-methyl-1-butyl, 3-methyl-1-butyl, 2-methyl-3-butyl, 2,2-dimethyl-1-propyl, 2-methyl-1-pentyl, 3-methyl-1-pentyl, 4-methyl-1-pentyl, 2-methyl-2-pentyl, 3-methyl-2-pentyl, 4-methyl-2-pentyl, 2,2-dimethyl-1-butyl, 3,3-dimethyl-1-butyl, 2-ethyl-1-butyl, n-butyl, isobutyl, sec-butyl, tert-butyl, n-pentyl, iso-pentyl, neopentyl, tert-pentyl, hexyl, etc., and longer chain alkyl groups such as heptyl and octyl, etc. Where a group as defined herein, for example, “alkyl” appears in a numerical range, for example, “C1-C8 alkyl” means an alkyl group which can be composed of 1 carbon atom, 2 carbon atoms, 3 carbon atoms, 4 carbon atoms, 5 carbon atoms, 6 carbon atoms, 7 carbon atoms, or 8 carbon atoms. For example, “C1-C4 alkyl” means an alkyl group which can be composed of 1 carbon atom, 2 carbon atoms, 3 carbon atoms, or 4 carbon atoms. As used herein, alkyl also includes cases in which the numerical range is unspecified.

The term “alkenyl” means an optionally substituted straight chain or an optionally substituted branch-chain monovalent hydrocarbon group having at least one C═C double bond.

The alkenyl group has, but is not limited to, 2-8 carbon atoms, for example, 2-6 carbon atoms or 2-4 carbon atoms. The double bond of these groups can be either cis-form or trans-form conformation, and should be understood to include both isomers. Examples of alkenyl groups include, but are not limited to, vinyl (CH═CH₂), 1-propenyl (CH₂CH═CH₂), isopropenyl (C(CH₃)═CH₂), butenyl, and 1,3-butadienyl, etc. Where an alkenyl as defined herein appears in a numerical range, for example, “C2-C8 alkenyl” means an alkenyl group which can be composed of 2 carbon atoms, 3 carbon atoms, 4 carbon atoms, 5 carbon atoms, 6 carbon atoms, 7 carbon atoms, or 8 carbon atoms. As used herein, alkenyl also includes cases in which the numerical range is unspecified.

The term “alkynyl” means an optionally substituted straight chain or an optionally substituted branch-chain monovalent hydrocarbon group having at least one C≡C triple bond. The alkynyl group has, but is not limited to, 2-8 carbon atoms, for example, 2-6 carbon atoms or 2-4 carbon atoms. Examples of alkynyl groups herein include, but are not limited to, ethynyl, 2-propynyl, 2-butynyl, and 1,3-butyldiynyl, etc. Where an alkynyl as defined herein appears in a numerical range, for example, “C2-C8 alkynyl” means an alkynyl group which can be composed of 2 carbon atoms, 3 carbon atoms, 4 carbon atoms, 5 carbon atoms, 6 carbon atoms, 7 carbon atoms, or 8 carbon atoms. As used herein, alkynyl also includes cases in which the numerical range is unspecified.

The term “cyclic hydrocarbon group” means a non-aromatic carbon-containing ring, including a saturated carbon ring (for example, cycloalkyl) or an unsaturated carbon ring (for example, cycloalkenyl). Carbon rings include a monocyclic carbon ring (having one ring), for example, a monocyclic cycloalkyl; a bicyclic carbon ring (having two rings), for example, a bicyclic cycloalkyl; and a polycyclic carbon ring (having two or more rings). The rings can be in a bridge linked or spiro ring relationship. The carbon ring (for example, cycloalkyl or cycloalkenyl) may have 3 to 8 carbon atoms, for example, 3 to 6 ring-forming carbon atoms or 3 to 5 ring-forming carbon atoms. Cyclic hydrocarbon groups of 3 to 20 carbon atoms can be, for example, cyclic hydrocarbon groups of 3 to 12 carbon atoms, such as cyclopropyl, cyclobutyl, cyclopentyl, cyclohexyl, cyclooctyl, etc.

The term “aryl” refers to any optionally substituted aromatic hydrocarbon group having 6 to 20, for example, 6 to 12 or 6 to 10 ring-forming carbon atoms, which may be a monocyclic aryl, a bicyclic aryl or more cyclic aryl. A bicyclic aryl group or polycyclic aryl group may be a group in which a monocyclic aryl group is fused to another independent ring, such as alicyclic ring, heterocyclic ring, aromatic ring, aromatic heterocyclic ring. A non-limiting example of a monocyclic aryl is a monocyclic aryl group having 6 to 12, 6 to 10 or 6 to 8 ring-forming carbon atoms, such as phenyl. A non-limiting example of a bicyclic aryl is, for example, naphthyl. Non-limiting examples of polycyclic aryl include, for example, phenanthrenyl, anthryl, and azulenyl.

The term “heteroaryl” refers to optionally substituted heteroaryl groups consisting of about 5 to 20, for example, 5 to 12 or 5 to 10 skeletal ring-forming atoms, of which at least one (for example, 1 to 4, 1 to 3, 1 to 2) is a heteroatom. The heteroatom is independently selected from, but not limited to, of the group consisting of oxygen, nitrogen, sulfur, phosphorus, silicon, selenium, and tin. Heteroaryls include monocyclic heteroaryl (having one ring), bicyclic heteroaryl (having two rings) or polycyclic heteroaryl (having two or more rings). In embodiments in which there are two or more heteroatoms in the ring, the two or more heteroatoms may be identical to each other, or some or all of the two or more heteroatoms may be different from each other. A bicyclic heteroaryl group or more polycyclic heteroaryl group may be a group (may collectively, fused ring heteroaryl group) in which a monocyclic heteroaryl group is fused to another independent ring, such as alicyclic ring, heterocyclic ring, aromatic ring, and aromatic heterocyclic ring. Non-limiting examples of heteroaryl groups include, but not limited to, pyrrolyl, furanyl, thienyl, imidazolyl, oxazolyl, pyrazolyl, pyridinyl, pyrimidinyl, pyrazinyl, quinolinyl, isoquinolinyl, tetrazolyl, triazolyl, triazinyl, benzofuranyl, benzothienyl, indolyl, and isoindolyl etc.

The term “heterocyclyl” refers to a non-aromatic heterocyclyl that includes either saturated or unsaturated heterocyclic rings (including unsaturated bonds), which do not have a fully conjugated π-electron system and can be classified as non-aromatic monocyclic ring, fused-polycyclic ring, bridged-ring or spiro-ring systems, in which one or more (for example, 1 to 4, 1 to 3, 1 to 2) of the ring-forming atoms are heteroatoms, such as an oxygen, nitrogen or sulfur atom. A heterocycle ring includes a monocyclic ring (comprising one ring), a bisheterocyclic ring (comprising two bridge-linked rings), a polyheterocyclic ring (comprising two or more bridge-linked rings), and a spirocylic ring. The heterocyclyl may have 3 to 20, for example, 3 to 10, 3 to 8, 4 to 8, 4 to 7, 5 to 8, or 5 to 6 ring-forming atoms. Non-limiting examples of heterocyclyls include: oxyranyl, thiiranyl, aziridinyl, azetidinyl, oxetanyl, thietanyl, tetrahydrofuranyl, pyrrolidinyl, oxazolidinyl, tetrahydropyrazolyl, pyrrolinyl, dihydrofuranyl, dihydrothienyl, piperidyl, tetrahydropyranyl, tetrahydrothionyl, morpholinyl, piperazinyl, dihydropyridyl, tetrahydropyridyl, Dihydropyranyl, tetrahydropyranyl, dihydrothionyl, azepanyl, oxepanyl, thiepanyl, oxa-azabicyclo[2.2.1]heptyl, and azaspiro[3.3]heptyl, etc.

Other group terms herein include: “hydroxyl” referring to the —OH group, “alkylthio” referring to the —SH group, “cyano” referring to the —CN group, and “carboxyl” referring to the —COOH group.

The present disclosure relates to a polymer for a photolithographic medium composition, having a structural unit represented by general formula (1) below

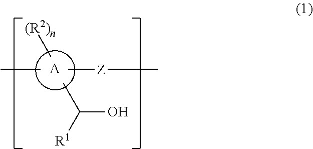

wherein A is a C6-C30 monocyclic or polycyclic aryl,
R² is each independently selected from the group consisting of hydrogen, halogen, cyano, a C1-C8 alkyl, a C2-C8 alkenyl, a C2-C8 alkynyl, —OR¹¹, —SR¹¹, —NR¹¹R¹², an ether group and an ester group;
Z is selected from the group consisting of a single bond, a C1-C10 alkylene substituted by 0 to 3 R^{A}, a C6-C20 arylene substituted by 0 to 3 R^{A}, a C6-C20 aralkylene substituted by 0 to 3 R^{A}, a C4-C20 heteroaralkylene substituted by 0 to 3 R^{A}, and a C1-C10 heteroalkylene substituted by 0 to 3 R^{A};
R¹ is selected from the group consisting of a C1-C10 alkyl substituted by 0 to 3 R^{A}, a C6-C20 aryl substituted by 0 to 3 R^{A}, heteroaryl containing 3 to 20 skeletal ring-forming atoms and containing one or more identical or different heteroatoms substituted by 0 to 3 R^{A}, a heterocyclyl containing 3 to 20 skeletal ring-forming atoms and containing one or more identical or different heteroatoms substituted by 0 to 3 R^{A}, and a cyclic hydrocarbon group containing 3 to 20 carbon atoms substituted by 0 to 3 R^{A};
R^{A} is each independently selected from the group consisting of hydrogen, halogen, cyano, a C1-C8 alkyl, a C2-C8 alkenyl, a C2-C8 alkynyl, —OR¹¹, —SR¹¹, —NR¹¹R¹², an ether group, and an ester group;
R¹¹ and R¹² are each independently selected from the group consisting of hydrogen, a C1-C8 alkyl, a C2-C8 alkenyl and a C2-C8 alkynyl; and
n is 1, 2 or 3.

Preferably, the structural unit represented by general formula (1) is the structural unit represented by general formula (2)

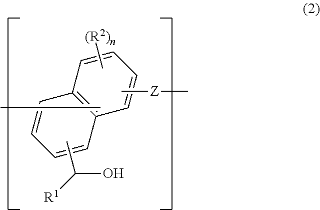

wherein R¹, R², n and Z are as defined in formula (1). It should be noted that, in the structural unit represented by general formula (2) above, the n R² can be located on the same benzene ring of the naphthalene ring, or on two different benzene rings of the naphthalene.

Preferably, the n R² are located on two different benzene rings of the naphthalene.

In one embodiment, R² is hydroxyl and n is 1 or 2.

In one embodiment, the structural unit represented by general formula (1) is the structural unit represented by general formula (3)

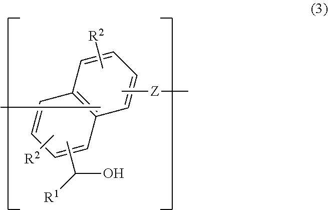

wherein R¹, R² and Z are as defined in formula (1). Preferably, R² is hydroxyl, i.e. there are two hydroxyls, and the two hydroxyls are located on two different benzene rings of the naphthalene ring.

In one embodiment, R¹ is selected from a C6-C20 aryl substituted by 0 to 3 R^{A}. Preferably, the C6-C20 aryl is selected from the group consisting of phenyl, naphthyl, fluorenyl, anthracenyl, phenanthrenyl, pyrenyl, biphenyl, and triphenyl.

In one embodiment, Z is selected from the following structural formulas

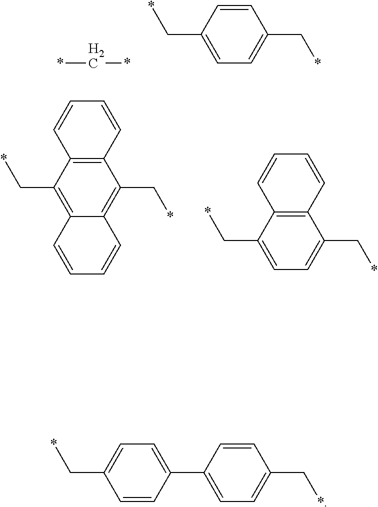

In the above structural formulas, * indicates the connecting position of the above structural formulas.

The polymer can be prepared by, first, performing a polymerization reaction between a compound having an active group R² and a monomer having cross-linking reactivity to form a polymer chain; and then adding one or more aldehyde compounds to the reaction system to modify the side chain of the polymer with a sec-hydroxyl structure.

The compound having an active group R² can be a naphthalene compound, for example, a naphthalene compound substituted by one or more R². For example, the naphthalene compound may be naphthol, dihydroxynaphthalene, dimercaptonaphthalene, naphthylamine, hydroxynaphthylamine, etc. Dihydroxynaphthalene may include 2,7-dihydroxynaphthalene, 2,6-dihydroxynaphthalene, 1,6-dihydroxynaphthalene, 2,3-dihydroxynaphthalene, and so on. Dimercaptonaphthalene may include 2,7-dimercaptonaphthalene, 2,6-dimercaptonaphthalene, 1,6-dimercaptonaphthalene, 2,3-dimercaptonaphthalene, and so on. Hydroxynaphthyamine may include 6-hydroxynaphthalene-2-amine, 7-hydroxynaphthalene-2-amine, and so on.

As monomers having cross-linking reactivity, aldehydes such as formaldehyde and paraformaldehyde, and diol compounds such as terephthalyl alcohol, biphenyldimethanol, naphthalenedimethanol, anthracenedimethanol, etc. can be used. The using amount of the monomer having cross-linking reactivity is 0.5 to 1.5 mol, especially 0.8 to 1.2 mol, based on 1 mol of the compound having an active group R² (e.g., the naphthalene compound described above).

The above polymerization reaction processes can be carried out in the presence of a catalyst. The catalyst may be an acid catalyst, such as inorganic acids and organic acids. For example, inorganic acids such as hydrochloric acid, sulfuric acid etc., and organic acids such as p-toluenesulfonic acid, acetic acid, benzenesulfonic acid, trifluoromethanesulfonate, etc. can be used. Lewis acids such as aluminum chloride and zinc chloride can also be used. The using amount of acid catalyst can be 0.0001 to 0.1 mol, based on 1 mol of the compound having a R² group (e.g., the naphthalene compound described above).

The above polymerization reaction can be carried out by using reaction solvents such as alcohol solvent (diethyl ether, cyclopentyl methyl ether, propylene glycol monomethyl ether, ethylene glycol dimethyl ether, etc.), esters (propylene glycol methyl ether acetate, ethyl lactate, ethyl acetate, butyl acetate, etc.), halogenated hydrocarbon (dichloromethane, chloroform, dichloroethane, etc.), or combination thereof. The temperature at which the above polymerization reaction is carried out can be 50 to 160° C.

In one embodiment, the polymer may further comprise the structural unit represented by general formula (4) and/or the structural unit represented by general formula (5)

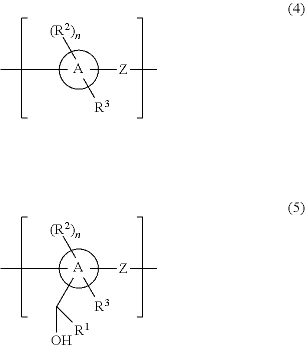

wherein R³ is selected from the group consisting of a C8-C20 aryl methylene, a C8-C30 aryl methine, and a C8-C40 aryl quaternary carbon group; and quaternary carbon group R¹, R², Z and n are as defined above.

In one embodiment, the structural unit represented by general formula (4) is the structural unit represented by general formula (6)

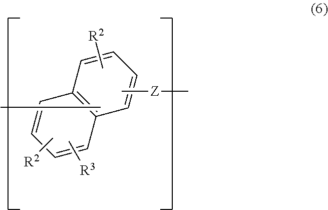

wherein R² is hydroxyl, R³ is C8-C20 aryl methylene such as anthracenyl methylene, pyrenyl methylene, naphthyl methylene, phenylmethylene, etc., is C8-C30 aryl methine such as diphenyl methyl, fluorenyl, etc., and is C8-C40 aryl quaternary carbon group such as triphenyl quaternary carbon group, phenylfluorenyl quaternary carbon group, etc. The structural unit represented by general formula (6) above have two hydroxyls, and the two hydroxyls are located on two different benzene rings of the naphthalene ring.

The structural unit represented by general formula (5) is the structural unit represented by general formula (7)

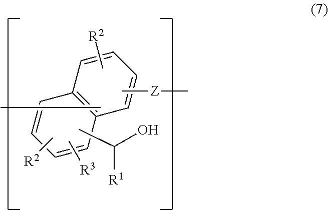

wherein R¹ is selected from a C6-C20 aryl substituted by 0 to 3 R^{A}. Preferably, the C6-C20 aryl is selected from the group consisting of phenyl, naphthyl, fluorenyl, anthracenyl, phenanthrenyl, pyrenyl, biphenyl, and triphenyl.
R² is hydroxyl;
R³ is a C8-C20 aryl methylene such as anthracenyl methylene, pyrenyl methylene, naphthyl methylene, phenylmethylene, etc.; or a C8-C30 aryl methine such as diphenyl methyl, fluorenyl, etc.; or a C8-C40 aryl quaternary carbon group such as triphenyl quaternary carbon group, phenylfluorenyl quaternary carbon group, etc. The structural unit represented by general formula (7) above have two hydroxyls, and the two hydroxyls are located on two different benzene rings of the naphthalene ring.

The polymer of the present disclosure may contain the structural unit represented by general formula (4) and/or the structural unit represented by general formula (5) above (particularly the structural unit represented by general formula (6) and/or the structural unit represented by general formula (7)). By introducing an R³ group having an aryl group into the structural unit represented by general formulas (4) to (7) above, the carbon content of the polymer of the present disclosure can be higher, and as a result, the polymer can have more excellent etching resistance.

By adding a reactive compound having R³ group to the polymerization reaction raw materials in the process of preparing the polymer as described above, a random copolymer comprising the structural units of formula (1)/(2)/(3), and the structural unit represented by general formula (4) and/or the structural unit represented by general formula (5) (particularly, the structural unit represented by general formula (6) and/or the structural unit represented by general formula (7)) can be formed. The used reactive compound having R³ group may include pyrenemethanol, anthracenemethanol, naphthalenemethanol, benzyl alcohol, diphenylmethanol, fluorenemethanol, triphenylmethanol, phenyl fluorenyl methanol, 1-phenethylalcohol, etc.

By adding an aldehyde compound to the reaction system after the polymerization reaction or during the polymerization reaction, a sec-hydroxyl structure can be introduced into the side chain of the polymer. The aldehyde compound may include one or more aldehydes, benzaldehyde, furfural, hydroxybenzaldehyde (including m-hydroxybenzaldehyde and p-hydroxybenzaldehyde), naphthaldehyde, anthraldehyde, biphenylcarboxaldehyde, pyrenecarboxaldehyde, pyridinecarboxaldehyde, cyclohexylaldehyde and so on. The using amount of the aldehyde compound can be 0.1 to 2.0 mol, based on 1 mol of the compound having a R² group (e.g., the naphthalene compound described above).

It should be noted that, not all the chain elements of polymers of this disclosure have a sec-hydroxyl structure introduced via the aldehyde compound, because the side chains of the polymers are modified after the formation of the polymer chain. The modification rate of the sec-hydroxyl structure is between 20% and 95%.

It should be noted that, in the prepared polymer, the R³ group can be located in the same structural unit as the sec-hydroxyl structure, as shown in the structural unit represented by general formula (5)/(7); and the R³ group can be located in a different structural unit from the sec-hydroxyl structure, i.e., the structural unit having the R³ group does not contain the sec-hydroxyl structure, as shown in the structural unit represented by general formula (4)/(6).

In one embodiment, the polymer has the weight average molecular weight of 500 to 20000 Da, preferably 1000 to 5000 Da; and the molecular weight distribution (PDI) of 1.1 to 4.0.

The polymer of the present disclosure contains sec-hydroxyl structure, which can improve its solubility and wettability of the material on the substrate, thereby improving the quality of film formation. In addition, the sec-hydroxyl structure is a reactive group, and can react with crosslinking agent to increase the crosslinking degree of the membrane layer, which in turn can improve the etching resistance of the membrane layer. Therefore, the above-mentioned polymers of the present disclosure have a high solubility in solvents. In particular, they have very good solubility in propylene glycol monomethyl ether acetate (PGMEA), propylene glycol monomethyl ether (PGME), and cyclohexanone, and exhibits excellent etching resistance.

### Photolithographic Medium Composition

It is generally required in industrial applications that the materials for etching-resistant medium layer should have even better etching resistance. In recent years, several efforts have been made to develop materials for medium layers and to apply these materials to multi-layer stacking processes. However, previous experience has shown that improving the etching resistance of materials (e.g., the pursuit of higher carbon content) often comes at the expense of solubility and film forming ability.

However, the polymer of the present disclosure maintains a carbon-rich structure (i.e., a polybenzene ring structure) while a sec-hydroxyl structure is introduced into the structure. The sec-hydroxyl structure can provide cross-linking sites during the film formation process of the material, which can improve the overall cross-linking density of the material, and consequently improve the etching resistance of the material. In addition, the sec-hydroxyl structure can serve as polar interaction sites, and has a strong movement ability, contributing to the improvement of the ability to interact with solvents. Thus, the solubility performance of the material is improved. The polymer of the present disclosure has excellent performance in the solubility and etching resistance, and the solubility of the polymer is improved while the etching resistance is considered. Thus, the polymer is very suitable as the material for an etching-resistant medium layer.

The present disclosure also relates to a photolithographic medium composition that contains an acid generating agent, a crosslinking agent, and a medium material, wherein the medium material is the above-mentioned polymer of the present disclosure.

The medium material contained in the photolithographic medium composition of the present disclosure may be above-mentioned polymers of the present disclosure, wherein based on the total weight of the photolithographic medium composition, the medium material is present in an amount of 0.1 to 30 wt %, preferably 2 to 15 wt %, more preferably 3 to 10 wt %.

The photolithographic medium composition of the present disclosure may contain, in addition to the medium material described above, an acid generating agent, a cross-linking agent, a surfactant, and a solvent, etc.

In one embodiment, based on the total weight of the photolithographic medium composition, the acid generating agent is present in an amount of 0.001 to 10 wt %, preferably 0.01 to 5 wt %.

The acid generating agent may comprise a thermal acid generating agent and an optional photo acid generating agent. In one embodiment, as the thermal acid generating agent, either ionic thermal acid generating agent or non-ionic thermal acid generating agent can be used. Ionic thermal acid generating agents include, but are not limited to, sulfonates such as carbocyclylaryl sulfonate and heteroaryl sulfonate, aliphatic sulfonate, benzene sulfonate, triflate, triethylamine dodecyl sulfonate; and ammonium p-toluenesulfonate. Non-ionic thermal acid generating agents include, but are not limited to, p-toluenesulfonic acid, methyl trifluoromethanesulfonate, cyclohexyl trifluoromethanesulfonate, cyclohexyl 2,4,6-triisopropyl benzenesulfonate, 2-nitrobenzyl p-toluenesulfonate, alkyl ester of organic sulfonic acid, benzoin tosylate, 2-nitrobenzyl toluenesulfonate, tris(2,3-dibromopropyl)-1,3,5-triazine-trione, dodecylbenzene sulphonic acid, oxalic acid, phthalic acid, phosphoric acid and camphorsulfonic acid, etc. and salts thereof, and the thermal acid generating agents disclosed in patent U.S. Ser. No. 10/429,737B2. Based on the total weight of the photolithographic medium composition, the content of the thermal acid generating agent is 0 to 10 wt %, such as 0.001 to 10 wt %, preferably 0.01 to 5 wt %, and more preferably 0.01 to 3 wt %.

The photo acid generating agent may include, for example, onium salts such as (tetra-t-butyl phenyl)-trifluoromethanesulfonate iodonium salt, triphenyl trifluoro methanesulfonate sulfonium salt, etc.; the compounds containing halogen for photo acid generating agents, such as phenyl bis(trichloromethyl)-s-triazine, etc.; benzoin tosylate, N-hydroxyl succinimidyl trifluoromethanesulfonate type photo acid generating agent; disulfonyl diazomethane type, etc. (onium salts, such as triphenylsulfonium trifluoromethanesulfonate, (p-tert-butoxyphenyl) diphenylsulfonium trifluoromethanesulfonate, tris(p-tert-butoxyphenyl) sulfonium trifluoromethanesulfonate, triphenylsulfonium p-toluenesulfonate; nitrobenzyl derivatives, such as 2-nitrobenzyl-p-toluenesulfonate, 2,6-dinitrobenzyl-p-toluenesulfonate and 2,4-dinitrobenzyl-p-toluenesulfonate; sulfonates, such as 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, such as bis(phenylsulfonyl) diazomethane, bis(p-toluenesulfonyl) diazomethane; glyoxime derivatives, such as bis-O-(p-toluenesulfonyl)-α-dimethyl glyoxime and bis-O-(n-butanesulfonyl)-α-dimethyl glyoxime; sulfonic acid ester derivatives of N-hydroxylimide compound, such as N-hydroxyl succinimide methanesulfonate, N-hydroxyl succinimide trifluoromethanesulfonate; and triazine compounds containing halogen, such as 2-(4-methoxyphenyl)-4,6-bis(trichloromethyl)-1,3,5-triazine and 2-(4-methoxynaphthalenyl)-4,6-bis(trichloromethyl)-1,3,5-triazine). In one embodiment, based on the total weight of the photolithographic medium composition, the content of the photo acid generating agent is 0 to 10 wt %, preferably 0 to 5 wt %, more preferably 0.01 to 3 wt %.

The photolithographic medium composition of the present disclosure may contain a cross-linking agent. In one embodiment, based on the total weight of the photolithographic medium composition, the amount of cross-linking agent is 0 to 10 wt %, such as 0.01 to 10 wt %.

The cross-linking agent used in the present disclosure may be glycoluril derivatives, melamine derivatives, biphenol derivatives etc., for example, hexahydroxymethylmelamine, hexamethoxymethylmelamine, hexamethoxyethylmelamine, and so on; tetrahydroxymethylglycoluril, tetramethoxyglycoluril, tetramethoxymethylglycoluril, and so on.

A surfactant may be added to the photolithographic medium composition formed according to the present disclosure. Surfactants may include, for example, polyoxyethylene alkyl ethers such as polyoxyethylene stearyl ether, polyoxyethylene lauryl (dodecyl) ether, polyoxyethylene hexadecyl ether, polyoxyethylene oleyl ether, etc.; polyoxyethylene alkyl-aryl ethers such as polyoxyethylene octylphenol ether, polyoxyethylene nonylphenol ether etc.; polyoxyethylene, polyoxypropylene block polymer, sorbitan monolaurate, sorbitan monopalmitate (hexadecanoate), sorbitan monostearate, sorbitan monooleate(9-octadecenoate), polyoxyethylene sorbitan monolaurate, sorbitan trioleate, sorbitan tristearate; polyoxyethylene sorbitan monopalmitate (hexadecanoate), polyoxyethylene sorbitan trioleate, polyoxyethylene sorbitan monostearate, polyoxyethylene sorbitan monooleate (9-octadecenoate), polyoxyethylene sorbitan tristearate, etc. In one embodiment, based on the total weight of the photolithographic medium composition, the content of the surfactant is 0 to 20 wt %, more preferably 0.0001 to 5 wt %.

Solvents for the photolithographic medium compositions formed according to the present disclosure include: single solvents such as alcohols, esters, ethers, cyclic ketones, etc., or mixed solvents thereof. Solvents include, but are not limited to: methyl ethyl ketone, cyclopentanone, cyclohexanone, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, ethyl 2-hydroxypropanoate, methyl 2-hydroxy-3-methyl butyrate, ethyl pyruvate, ethyl acetate, butyl acetate, ethyl lactate, butyl lactate, methyl 3-methoxypropionate, ethyl 3-methoxypropionate, ethyl 3-ethoxypropionate, methyl 3-ethoxypropionate, methyl pyruvate, N,N-dimethylformamide, dimethyl sulfoxide, N-methylpyrrolidone, etc. In one embodiment, based on the total weight of the photolithographic medium composition, the content of the solvent is 70 to 99 wt %, and more usually 85 to 99 wt %.

The present disclosure also relates to a photolithographic medium layer formed from above-mentioned photolithographic medium composition of the present disclosure. The method for forming the medium layer is not particularly limited, and the medium layer can be formed by applying the photolithographic medium composition on a substrate through a method known to those skilled in the art such as coating methods or printing methods (known as spin coating, screen printing, etc.), then volatilizing the organic solvents. After film formation, the cross-linking reaction can be promoted by baking and the like. In one embodiment, the baking temperature may be 80 to 400° C., in particular 200 to 400° C.

Hereinafter, examples are provided to further illustrate the disclosure.

### Synthesis Example 1

To a 200 ml reaction flask with magnetic agitation and condensed reflux, 16 g (0.1 mol) of 2,7-dihydroxynaphthalene, 11.1 g (0.08 mol) of terephthalyl alcohol, 1.9 g (0.01 mol) of p-toluenesulfonic acid monohydrate and 100 mL of cyclopentyl methyl ether were added, stirred at 60° C. for 10 minutes to completely dissolve, and heated to reflux and reacting for 24 hours. After cooling to room temperature, 15.9 g (0.15 mol) of benzaldehyde was added, and heated again to reflux and reacting for 6 hours. At the end of the reaction, the product was precipitated with 500 ml of n-hexane and filtered. It was washed sequentially with deionized water and n-hexane and dried in vacuum oven at 50° C., and the polymer A1 was obtained. The product had the weight average molecular weight of 2500 Da, and PDI of 2.5, as determined by gel chromatography.

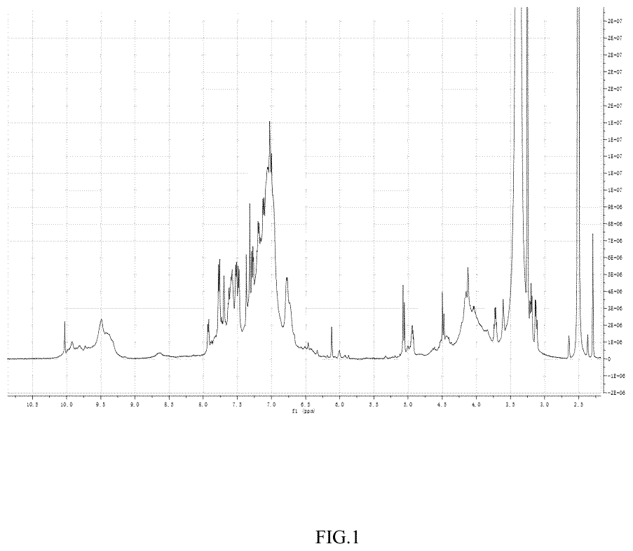

The chemical structure was confirmed by 500 MHz ¹H-NMR, the spectrum was shown in FIG. 1, δ(A1): (ppm, DMSO, TMS): 9.11-10.00 (−OH), 6.30-8.00 (Ph-H, >CH—OH), 6.12 (>CH—OH), 5.05 (Ph-CH₂OH), 4.50 (Ph-CH₂—OH), 3.68-4.75 (Ph-CH₂-Ph).

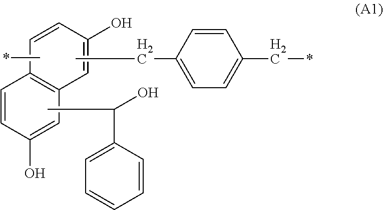

### Synthesis Example 2

Polymer A2 was obtained by the same operation as in Synthesis example 1, except that naphthaldehyde was used to replace benzaldehyde. It had the weight average molecular weight of 1700 Da, and PDI of 2.2.

The chemical structure was confirmed by 500 MHz ¹H-NMR, δ (A2) (ppm, DMSO, TMS): 9.35-00.05 (—OH), 6.60-8.59 (Ph-H, >CH—OH), 6.30 (>CH—OH), 5.05 (Ph-CH₂OH), 4.50 (Ph-CH₂—OH), 4.03-4.77 (Ph-CH₂-Ph).

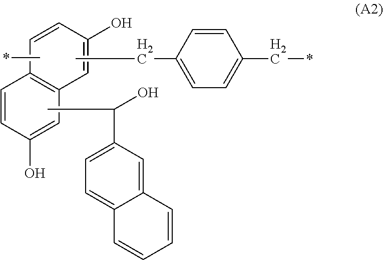

### Synthesis Example 3

Polymer A3 was obtained by the same operation as in Synthesis example 1, except that pyridine-2-carboxaldehyde was used to replace benzaldehyde. It had the weight average molecular weight of 2200 Da, and PDI of 1.9.

The chemical structure was confirmed by 500 MHz ¹H-NMR, δ (A3) (ppm, DMSO, TMS): 9.27-9.92 (—OH), 6.68-8.80 (Ph-H, >CH—OH), 6.31 (>CH—OH), 5.07 (Ph-CH₂OH), 4.50 (Ph-CH₂—OH), 3.78-4.32 (Ph-CH₂-Ph).

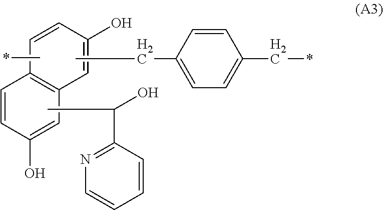

### Synthesis Example 4

Polymer A4 was obtained by the same operation as in Synthesis example 1, except that cyclohexylcarboxaldehyde was used to replace benzaldehyde. It had the weight average molecular weight of 2200 Da, and PDI of 2.0.

The chemical structure was confirmed by 500 MHz ¹H-NMR, δ (A4) (ppm, DMSO, TMS): 9.25-9.76 (—OH), 6.60-7.85 (Ph-H, >CH—OH), 4.53 (>CH—OH), 5.07 (Ph-CH₂OH), 4.49 (Ph-CH₂—OH), 3.78-4.35 (Ph-CH₂-Ph), 1.32-1.89 (—CH₂—).

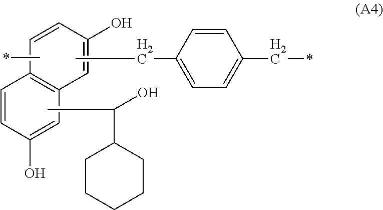

### Synthesis Example 5

Polymer A5 was obtained by the same operation as in Synthesis example 1, except that 1,6-dihydroxynaphthalene was used to replace 2,7-dihydroxynaphthalene. It had the weight average molecular weight of 4200 Da, and PDI of 2.6.

The chemical structure was confirmed by 500 MHz ¹H-NMR, 6 (A6) (ppm, DMSO, TMS): 8.50-9.73 (—OH), 6.21-8.20 (Ph-H, >CH—OH), 6.12 (>CH—OH), 5.07 (Ph-CH₂OH), 4.50 (Ph-CH₂—OH), 3.64-4.30 (Ph-CH₂-Ph).

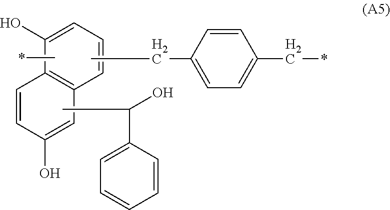

### Synthesis Example 6

Polymer A6 was obtained by the same operation as in Synthesis example 1, except that 2-hydroxynaphthalene (0.08 mol) was used to replace a portion of the 2,7-dihydroxynaphthalene (0.04 mol) in Synthesis Example 1. It had the weight average molecular weight of 5000 Da, and PDI of 3.0.

The chemical structure was confirmed by 500 MHz ¹H-NMR, δ (A6) (ppm, DMSO, TMS): 9.29-9.98 (—OH), 6.56-8.20 (Ph-H, >CH—OH), 6.12 (>CH—OH), 5.07 (Ph-CH₂OH), 4.50 (Ph-CH₂—OH), 3.80-4.39 (Ph-CH₂-Ph).

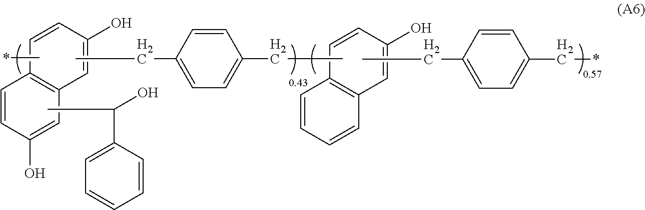

### Synthesis Example 7

Polymer A7 was obtained by the same operation as in Synthesis example 1, except that anthracenemethanol (0.02 mol) was used to replace a portion of the α-benzedimethanol (0.02 mol) in Synthesis Example 1. It had the weight average molecular weight of 3100 Da, and PDI of 2.6.

The chemical structure was confirmed by 500 MHz ¹H-NMR, δ (A7) (ppm, DMSO, TMS): 9.18-10.05 (—OH), 6.36-8.77 (Ph-H, >CH—OH), 6.12 (>CH—OH), 5.07 (Ph-CH₂OH), 4.50 (Ph-CH₂—OH), 3.65-4.63 (Ph-CH₂-Ph).

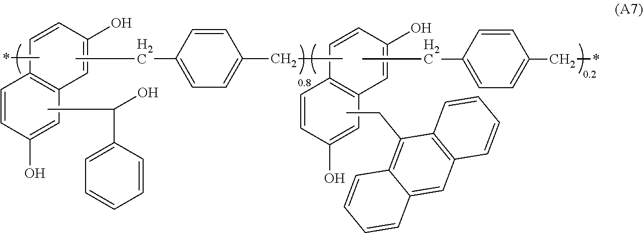

### Comparative Synthesis Example 1

To a 200 ml reaction flask with magnetic agitation and condensed reflux, 14.4 g (0.1 mol) of 2-hydroxynaphthalene, 3 g of paraformaldehyde, and 100 ml of cyclopentyl methyl ether were added, stirred at 60° C. for 10 minutes to completely dissolve. 0.95 g of p-toluenesulfonic acid was then added and heated to reflux and reacting for 24 hours. At the end of the reaction, the product was precipitated with 500 ml of n-hexane and filtered. It was washed sequentially with deionized water and n-hexane and dried in vacuum oven at 50° C., and the target polymer B1 was obtained. The product had the weight average molecular weight of of 3300 Da, and PDI of 2.5, as determined by gel chromatography.

The chemical structure was confirmed by 500 MHz ¹H-NMR, δ (ppm, DMSO, TMS): 9.52-9.92 (—OH), 7.00-8.22 (Ph-H), 4.30-4.68 (Ph-CH₂-Ph)

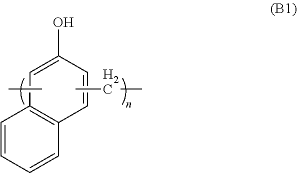

### Comparative Synthesis Example 2

To a 200 ml reaction flask with magnetic agitation and condensed reflux, 16 g (0.1 mol) of 2,7-dihydroxynaphthalene, 11.1 g (0.08 mol) of terephthalyl alcohol, 1.9 g (0.01 mol) of p-toluenesulfonic acid monohydrate and 100 mL of cyclopentyl methyl ether were added, stirred at 60° C. for 10 minutes to completely dissolve, and heated to reflux and reacting for 24 hours. At the end of the reaction, the product was precipitated with 500 ml of n-hexane and filtered. It was washed sequentially with deionized water and n-hexane and dried in vacuum oven at 50° C., and the target product B-2 was obtained. The product had the weight average molecular weight of 2300 Da, and PDI of 2.3, as determined by gel chromatography.

The chemical structure was confirmed by 500 MHz ¹H-NMR, δ (B2): (ppm, DMSO, TMS): 9.11-10.00 (—OH), 6.30-8.00 (Ph-H), 5.05 (Ph-CH₂OH), 4.50 (Ph-CH₂—OH), 3.60-4.55 (Ph-CH₂-Ph).

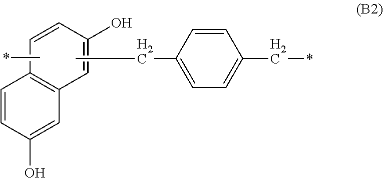

### Preparation and Performance Testing of Photolithographic Medium Compositions

### Example 1

### (1) Solubility Evaluation

Polymer A1 was respectively dissolved in 100 g of propylene glycol monomethyl ether acetate, propylene glycol monomethyl ether and cyclohexanone at 25° C. The maximum dissolution amount of the polymer was recorded. If the maximum dissolution amount is 20 g or more, the solubility is considered as “excellent”; if the maximum dissolution amount is between 10 g and 20 g, the solubility is considered as “good”; and, if the maximum dissolution amount is less than 10 g, the solubility is considered as “poor”.

### (2) Optical Test

0.4 g of polymer A1 obtained in Synthesis example 1 was dissolved in 10 g of mixed solution of propylene glycol monomethyl ether acetate and propylene glycol monomethyl ether with a volume ratio of 7:3. 8 mg of p-toluenesulfonic acid, 0.08 g of acid crosslinking agent Powderlink 1174, and 2 mg of surfactant polyoxyethylene dehydrated sorbitan trioleate were added. The solution was well mixed and filtered with a 0.22 m filter to obtain the photolithographic medium composition.

The composition was spin coated on a silicon wafer at 1500 rpm and heated and baked at 250° C. for 60 seconds to form a thin film. The thickness of the thin film was measured by spectroscopic ellipsometer, and the refractive index n and the extinction coefficient k at 193 nm were investigated.

### (3) Evaluation of Etching Resistance

The obtained thin films were respectively etched for 60 seconds at a power of 300 W, a flow rate of 40 sccm and a pressure of 8 mtorr in CF4 plasma gas, and for 30 seconds at a power of 50 W, a flow rate of 8 sccm and a pressure of 8 mTorr in O2 plasma gas. The thickness of the thin films was measured by spectroscopic ellipsometer to calculate the thickness change value of thin films. Thus, the etching rate of the obtained thin films in two plasma gases was calculated according to equation 1-1.

Etching rate (nm/min)=the thickness change value of film (nm)/time (min) (equation 1-1)

All data are aggregated and presented in Table 1-1.

### Example 2

Except for the replacement of A1 by A2, the same composition preparation and testing methods as in Example 1 were used.

### Example 3

Except for the replacement of A1 by A3, the same composition preparation and testing methods as in Example 1 were used.

### Example 4

Except for the replacement of A1 by A4, the same composition preparation and testing methods as in Example 1 were used.

### Example 5

Except for the replacement of A1 by A5, the same composition preparation and testing methods as in Example 1 were used.

### Example 6

Except for the replacement of A1 by A6, the same composition preparation and testing methods as in Example 1 were used.

### Example 7

Except for the replacement of A1 by A7, the same composition preparation and testing methods as in Example 1 were used.

### Comparative Example 1

Except for the replacement of A1 by B1, the same composition preparation and testing methods as in Example 1 were used.

### Comparative Example 2

Except for the replacement of A1 by B2, the same composition preparation and testing methods as in Example 1 were used.

TABLE 1-1

| | | | | | | | CF₄ | O₂ |
|---|---|---|---|---|---|---|---|---|
| | | | | | | | etching | etching |
| | | solubility | | | | | rate | rate |
| Examples | materials | PMA | PGME | cyclohexanone | n | k | nm/min | nm/min |
| Example 1 | A1 | excellent | excellent | excellent | 1.56 | 0.60 | 12 | 28 |
| Example 2 | A2 | excellent | excellent | excellent | 1.36 | 0.48 | 12 | 27 |
| Example 3 | A3 | excellent | excellent | excellent | 1.50 | 0.59 | 13 | 29 |
| Example 4 | A4 | excellent | excellent | excellent | 1.50 | 0.57 | 13 | 29 |
| Example 5 | A5 | excellent | excellent | excellent | 1.58 | 0.63 | 12 | 28 |
| Example 6 | A6 | excellent | excellent | excellent | 1.52 | 0.63 | 12 | 28 |
| Example 7 | A7 | excellent | excellent | excellent | 1.46 | 0.34 | 12 | 27 |
| CE 1 | B1 | excellent | excellent | excellent | 1.36 | 0.31 | 13 | 33 |
| CE 2 | B2 | excellent | excellent | excellent | 1.51 | 0.57 | 14 | 34 |

As can be seen from the statistical results in Table 1-1, under the test conditions for this experiment, the etching rates of Examples 1-7 were superior to those of Comparative example 1 and Comparative example 2, which shows that the polymers A1-A7 used in Examples 1-7 are superior in etching resistance, as compared with the polymers used in the Comparative examples. Comparison of the structure of polymers A1-A7 and B2 and the corresponding etching test results shows that the introduction of sec-hydroxyl structures into the polymer is beneficial for improving the etching resistance of the material.

Furthermore, it can be seen from the statistical results in Table 1-1 that, the polymers A-1 to A-7 used in Examples 1-7 all showed relatively excellent solubility under the conditions of this experiment, which was comparable to the levels of Comparative examples. This suggests that this polymer structure has no negative effect on solubility.

In summary, the polymer of the present disclosure having a sec-hydroxyl structure can improve the etching resistance of the composition, while balancing the solubility.

In the foregoing, the present disclosure has been described incorporating preferred embodiments, but these embodiments are illustrative only and are intended for illustration purposes. On this basis, it is possible to make various substitutions and improvements to this application, all of which fall within the scope of protection of this application.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. A polymer for a photolithographic medium composition, having a structural unit represented by general formula (2) below 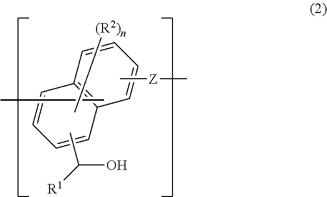
wherein R² is hydroxyl;
Z is selected from the group consisting of a single bond, a C1-C10 alkylene substituted by 0 to 3 R^{A}, a C6-C20 arylene substituted by 0 to 3 R^{A}, a C6-C20 aralkylene substituted by 0 to 3 R^{A}, a C4-C20 heteroaralkylene substituted by 0 to 3 R^{A}, and a C1-C10 heteroalkylene substituted by 0 to 3 R^{A};
R¹ is selected from the group consisting of a C1-C10 alkyl substituted by 0 to 3 R^{A}, a C6-C20 aryl substituted by 0 to 3 R^{A}, a heteroaryl containing 3 to 20 skeletal ring-forming atoms and containing one or more identical or different heteroatoms substituted by 0 to 3 R^{A}, a heterocyclyl containing 3 to 20 skeletal ring-forming atoms and containing one or more identical or different heteroatoms substituted by 0 to 3 R^{A}, and a cyclic hydrocarbon group containing 3 to 20 carbon atoms substituted by 0 to 3 R^{A};
R^{A} is each independently selected from the group consisting of hydrogen, halogen, cyano, a C1-C8 alkyl, a C2-C8 alkenyl, a C2-C8 alkynyl, —OR¹¹, —SR¹¹, —NR¹¹R¹², an ether group, and an ester group;
R¹¹ and R¹² are each independently selected from the group consisting of hydrogen, a C1-C8 alkyl, a C2-C8 alkenyl, and a C2-C8 alkynyl; and
n is 2;
wherein the weight average molecular weight of the polymer is 500 to 20000 Da; and the molecular weight distribution of the polymer is 1.1 to 4.0.

18. The polymer according to claim 17, wherein the structural unit represented by general formula (2) is the structural unit represented by general formula (3) 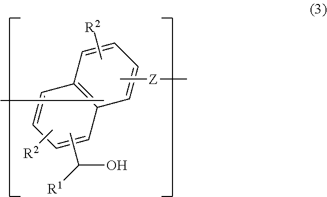
wherein R¹, R² and Z are as defined in claim 17.

19. The polymer according to claim 17, wherein R¹ is selected from a C6-C20 aryl substituted by 0 to 3 R^{A}.

20. The polymer according to claim 19, wherein the C6-C20 aryl is selected from the group consisting of phenyl, naphthyl, fluorenyl, anthracenyl, phenanthrenyl, pyrenyl, biphenyl, and triphenyl.

21. The polymer according to claim 17, wherein Z is selected from the following structural formulas

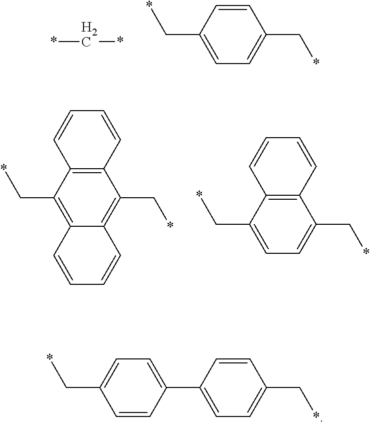

22. The polymer according to claim 17, wherein the polymer further comprises the structural unit represented by general formula (6) and/or the structural unit represented by general formula (7) 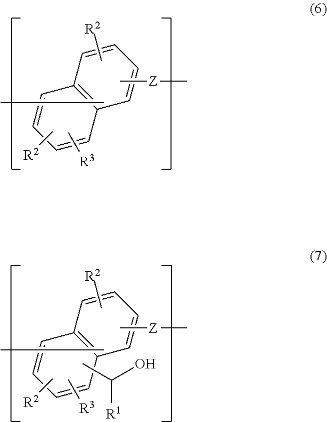
wherein R² is hydroxyl; R³ is a C8-C20 aryl methylene, a C8-C30 aryl methine, or a C8-C40 aryl quaternary carbon group; and
R¹ is selected from a C6-C20 aryl substituted by 0 to 3 R^{A}, Z is as defined in claim 17.

23. The polymer according to claim 22, wherein the C8-C20 aryl methylene is anthracenyl methylene, pyrenyl methylene, naphthyl methylene, or phenylmethylene.

24. The polymer according to claim 22, wherein the C8-C30 aryl methine is diphenyl methyl or fluorenyl.

25. The polymer according to claim 22, wherein the C8-C40 aryl quaternary carbon group is triphenyl quaternary carbon group or phenylfluorenyl quaternary carbon group.

26. The polymer according to claim 22, wherein the C6-C20 aryl is selected from the group consisting of phenyl, naphthyl, fluorenyl, anthracenyl, phenanthrenyl, pyrenyl, biphenyl, and triphenyl.

27. The polymer according to claim 17, wherein the weight average molecular weight of the polymer is 1000 to 5000 Da.

28. A photolithographic medium composition comprising an acid generating agent, a crosslinking agent, and a medium material, wherein the medium material is the polymer of claim 17.

29. The photolithographic medium composition according to claim 28, wherein based on the total weight of the photolithographic medium composition, the amount of the medium material is 0.1 to 30 wt %;
based on the total weight of the photolithographic medium composition, the amount of the cross-linking agent is 0.01 to 10 wt %; and
based on the total weight of the photolithographic medium composition, the amount of the acid generating agent is 0.001 to 10 wt %.

30. The photolithographic medium composition according to claim 29, wherein based on the total weight of the photolithographic medium composition, the amount of the medium material is 2 to 15 wt %.

31. The photolithographic medium composition according to claim 29, wherein based on the total weight of the photolithographic medium composition, the amount of the medium material is 3 to 10 wt %.

32. The photolithographic medium composition according to claim 28, wherein the acid generating agent comprises a thermal acid generating agent and an optional photo acid generating agent, and
wherein based on the total weight of the photolithographic medium composition, the content of the thermal acid generating agent is 0.001 to 10 wt %; and
based on the total weight of the photolithographic medium composition, the content of the photo acid generating agent is 0.01 to 10 wt %.

33. The photolithographic medium composition according to claim 32, wherein based on the total weight of the photolithographic medium composition, the content of the thermal acid generating agent is preferably 0.01 to 5 wt %.

34. The photolithographic medium composition according to claim 32, wherein based on the total weight of the photolithographic medium composition, the content of the thermal acid generating agent is more preferably 0.01 to 3 wt %.

35. The photolithographic medium composition according to claim 32, wherein based on the total weight of the photolithographic medium composition, the content of the photo acid generating agent is preferably 0.01 to 5 wt %.

36. The photolithographic medium composition according to claim 32, wherein based on the total weight of the photolithographic medium composition, the content of the photo acid generating agent is 0.01 to 3 wt %.

37. The photolithographic medium composition according to claim 28, further comprising a surfactant and a solvent.

38. The photolithographic medium composition according to claim 37, wherein based on the total weight of the photolithographic medium composition, the content of the surfactant is 0 to 20 wt %; and
based on the total weight of the photolithographic medium composition, the content of the solvent is 70 to 99 wt %.

39. The photolithographic medium composition according to claim 38, wherein based on the total weight of the photolithographic medium composition, the content of the surfactant is more preferably 0.0001 to 5 wt %.

40. The photolithographic medium composition according to claim 38, wherein based on the total weight of the photolithographic medium composition, the content of the solvent is 85 to 99 wt %.

41. A photolithographic medium layer formed from the photolithographic medium composition of claim 28.
